(19) United States
(12) Patent Application Publication
(10) Pub. No.: US 2026/0227176 A1
(43) Pub. Date: Aug. 6, 2026

(54) METHOD FOR DETERMINING DISPLACEMENT MAPS, METHOD FOR ADJUSTING PARAMETERS FOR A BONDING PROCESS, AND COMPOSITE SUBSTRATE PRODUCED USING SAID PARAMETERS, AND SYSTEM FOR PRODUCING A COMPOSITE SUBSTRATE

(71) Applicant: EV Group E. Thallner GmbH, ST. FLORIAN AM INN (AT)

(72) Inventor: Thomas PLACH, ST. FLORIAN AM INN (AT)

(21) Appl. No.: 19/150,985

(22) PCT Filed: Jan. 25, 2023
(86) PCT No.: PCT/EP2023/051780

§ 371 Date: Jul. 25, 2025

(51) Int. Cl. G01B 11/06; G01B 11/255; H10P 10/00; H10P 72/00

(52) U.S. Cl. CPC G01B 11/06; G01B 11/255; H10P 10/12; H10P 72/0428; H10P 72/0616; G01B 2210/56

(57) ABSTRACT

A method for providing a displacement map comprising,
providing a first substrate and a second substrate,
measuring the first substrate to determine at least a first geometrical parameter, and the second substrate to determine at least a second geometrical parameter,
bonding the first substrate to the second substrate to form a composite substrate,
measuring the bonded composite substrate to determine at least one measured third geometrical parameter, and
providing at least one simulated third geometrical parameter for the bonded composite substrate based on a composite model, wherein the simulated third geometrical parameter is simulated in dependence of the at least one first geometrical parameter, the at least one second geometrical parameter and a preliminary displacement map by means of an analysis and/or simulation device wherein the preliminary displacement map is generated by means of the analysis and/or simulation device.

### CROSS REFERENCE TO RELATED APPLICATION

This application is a National Stage application of PCT/EP2023/051780, filed Jan. 25, 2023, which is incorporated by reference in its entirety herein.

### BACKGROUND

The present invention relates to a method for providing displacement maps, a method of setting parameters for a bonding process, a composite substrate made with such parameters, and an apparatus for making a composite substrate.

In the prior art, several methods exist for bonding substrates, especially wafers, together. The bonding process is called bonding. Bonding can be divided into two major groups, permanent bonding and temporary bonding. In temporary bonding, the substrates are bonded together such that at least one of the two substrates can be processed. The second substrate serves as a mechanically stabilizing carrier. After the first substrate, the product substrate, has been processed, it can either be transferred to a third substrate, cut at the carrier substrate, or removed from the carrier substrate. In any case, the carrier substrate is removed in one way or another, thus bonding the product substrate only temporarily. Precise alignment of the two substrates to each other is not important. If the two substrates are aligned to within half a millimeter of each other, this is usually sufficient from a process engineering point of view.

In contrast, permanent bonding creates a permanent connection between two substrates. This permanent bond is usually based on a so-called “direct bonding”. A direct bond is a direct connection between two substrates via their existing substrate surfaces, without having to create a melting process, a phase transformation or a diffusion. Direct bonds are very often also referred to as “fusion bonds”. The first important application of direct bonding was the joining of two oxidized substrates, one of which was prepared using the so-called SmartCut® technology. In SmartCut® technology, ions, particularly hydrogen atoms, are shot into a certain depth of the substrate. The substrate surface is oxidized and bonded to a second substrate, which also has an oxidized substrate surface. An additional heat treatment ensures that the prepared substrate breaks along the implantation plane and its upper part can be removed. the remaining substrate surface is still planarized and then sits on a buried oxide layer. Functional units such as microchips can then be fabricated in this remaining substrate surface. Stray currents are prevented by the existing oxide layer. This process has the advantage that after contacting the two substrates, known as pre-bonding, the composite substrate can be exposed to any high temperature, since there are not yet any functional units in the substrates that could be damaged by the temperature.

Meanwhile, there are method steps in which a substrate already has functional units before it is bonded to a second substrate by a direct bond. Correspondingly, the temperatures have to be lower. Another problem that arises, especially for substrates that are already processed and preferably provided with functional units, is that these substrates must be precisely aligned to the respective second substrate before direct bonding. Alignment is usually necessary because the functional units of one substrate must communicate with the functional units of the second substrate. The communication is usually done via copper lines that extend from the functional units, usually through an oxide layer, to the substrate surface. If these copper lines are created in silicon or silicon oxide, they are called through silicon vias (TSVs). There are countless such TSVs on a substrate surface. TSVs are the most important but not the only structures that need to be aligned with each other.

Another serious problem, which has arisen especially in recent years, is the local, on-site displacements between the substrate surfaces of the substrates to be bonded, which occur during bonding. In direct bonding, one substrate, preferably the lower one, is fixed to a substrate holder, while the second substrate initially contacts the first substrate in a point contact, especially centrically. After this point contacting, the second substrate is brought into contact with the first substrate in a controlled manner, sometimes also in an uncontrolled manner. The contacting takes place by the formation of a bond wave, which propagates from the contacting point to the periphery. During the propagation of the bond wave, partial areas of the substrate surfaces of both substrates can be displaced relative to each other. In particular, the areas directly in front of, along or behind the bond wave are subject to a correspondingly large displacement. As a result, structures on the two substrates that are opposite each other and should actually have been bonded to each other may no longer contact each other or may contact each other only poorly.

The measurement and analysis of substrate surfaces has been a well-known method for years to evaluate the quality of different processes. However, this method is used to evaluate substrate surfaces after a coating, exposure or etching process. In particular, it is also easy to do so because the treated substrate surface is readily accessible to optical systems after the corresponding process. The most common application of the method is in the measurement and evaluation of the structures produced by a lithographic process in a photographic coating. An idealized model of the structures exists in the computer. The structures are then transferred to a photoresist by a lithographic process. Particularly in the case of photolithography, diffraction phenomena or misorientations of the template relative to the substrate result in a non-optimal imaging of the structures of the photomask into the photoresist. By comparing the structures actually created in the photoresist with the ideal structures of the computer, a displacement map can be generated. This displacement map consists of a set of displacement vectors at as many positions as possible. Each displacement vector indicates how the real structure position differs from the ideal structure position. By calculating the change in displacement vectors as a function of location, corresponding distortion maps could then still be calculated.

One problem in the prior art is that the displacement maps between the substrate surfaces of two substrates bonded together are not necessarily directly accessible. After a bonding process, a transmission method must be used to examine the substrate surfaces that have been bonded together. For example, it would be conceivable to use an infrared light and an appropriate infrared camera to transilluminate two silicon wafers that have been bonded together.

In most cases, however, the substrates to be transilluminated, which are usually silicon substrates, are coated with layers, especially metallic layers, or already have functional units that also have metallic parts. Since metals are not infrared transparent, measurement of the interface is made difficult or even impossible. The problem in the prior art, however, is still to bond the substrates to each other in such a way that they are joined together in a controllable manner, over the entire surface, in such a way that their structures, which are aligned with each other, experience a minimum displacement with respect to each other at each position, in particular none at all. Thus, all structures of a first substrate must be contacted and bonded to their corresponding structures of a second substrate with minimal error. The problem is not only the fact that the structures already deviate from an ideal position during their manufacture and thus, in the worst case, each substrate has a displacement map describing the deviation of the structures from their ideal positions, but also that these displacement maps can change during bonding due to the mechanical properties, in particular in front of, on and behind the bond wave. In particular, the change in displacements of the structures during the bonding process is a serious problem for structure sizes in the micrometer and nanometer ranges.

The prior art does not solve, or at least does not sufficiently solve, the problem of determining the displacement maps between the two substrate surfaces of a composite substrate bonded together.

### SUMMARY

The present invention thus makes it its task to provide a quantitative evaluation for a bonding process, which can be used independently of the material composition of the substrates bonded together and preferably does not require any further measurement steps, in order to optimize parameters for the bonding process on the basis of the quantitative evaluation.

The present invention solves the problem with the disclosed methods, with the disclosed composite substrate and the disclosed apparatus. Further advantageous embodiments can be found in the figures and the description.

According to a first aspect, there is provided a method for providing a displacement map, preferably used for qualitative evaluation of a performed bonding process, comprising,
providing a first substrate and a second substrate,
measuring the first substrate to determine at least one first geometrical parameter, in particular a macroscopic and/or microscopic first geometrical parameter, and the second substrate to determine at least one second geometrical parameter, in particular a macroscopic and/or microscopic second geometrical parameter,
bonding the first substrate to the second substrate to form a composite substrate,
measuring the bonded composite substrate to determine at least one measured third geometrical parameter,
providing at least one simulated third geometrical parameter for the bonded composite substrate based on a composite model, wherein the simulated third geometrical parameter is provided in dependence on the at least one first geometrical parameter, the at least one second geometrical parameter, and a preliminary displacement map indicating a local deviation from a desired ideal position is simulated on the basis of the composite model by means of an analysis and/or simulation device, wherein the preliminary displacement map is created by means of the analysis and/or simulation device and can preferably be adapted in the composite model, in particular adapted to compensate for deviations between the simulated third geometrical parameter and the measured third geometrical parameter,
comparing the at least one simulated third geometrical parameter with the at least one measured third geometrical parameter, and
providing as a displacement map that preliminary displacement map for which the deviation between the simulated third geometrical parameter and the at least one measured third geometrical parameter is minimal.

### BRIEF DESCRIPTION OF THE DRAWINGS

Further advantages, properties and details of the invention will be apparent from the following description of preferred embodiments and from the drawings.

FIG. 1 shows a process flow of a method according to a preferred embodiment of the present invention; and

FIG. 2 shows a schematic representation of some method steps of the method of FIG. 1.

In the figures, identical components or components with the same function are marked with the same reference signs.

### DETAILED DESCRIPTION

Contrary to the prior art, the displacement map is determined by means of a simulation which predicts the appearance and shape of the composite substrate. The simulation initially takes into account the geometrical prerequisites, i.e. the at least one first geometrical parameter and the at least one second geometrical parameter, of the first and second substrate.

The displacement map reflects the respective locally existing deviation between the intended relative position of the first substrate to the second substrate to the actually adopted relative position of the first substrate and the second substrate, in particular with respect to their respective substrate surfaces. Thus, the displacement map indicates by how much local sections of the first and second substrates have been bonded laterally offset or displaced from their ideal position and thus are not congruent with each other. The displacement map can be thought of as a two-dimensional vector array that assigns size and direction to each subsection between the first substrate and the second substrate for the lateral offset present in each case. If the offset is zero, the first substrate and second substrate lie on top of each other in this subsection as desired, or the subsections to be bonded are arranged essentially congruent with each other. It has been shown that the respective locally occurring lateral or sideways displacements of the subsections during bonding influence the geometry, i.e. the outer shape of the composite substrate. In addition, it has been surprisingly shown that simulations can be used to determine the displacement map by using a composite model to compare the predicted geometry with the real geometry of the composite structure, taking into account the geometries of the first substrate and the second substrate, and adjusting the preliminary displacement maps until the predicted geometry and the real geometry essentially match. This makes it possible to determine the displacement map even for bonded composite substrates, in particular their interface between the first substrate and the second substrate, without using a transmission method.

Preferably, the preliminary displacement map is adjusted at least once to find the preliminary displacement map with the minimum deviation between the simulated third geometrical parameter and the at least one measured third geometrical parameter.

For an unstructured first or second substrate, imagine an idealized, perfect, highly symmetric grid with equidistant grid lines on the substrate surfaces to be bonded. The grid lines represent the mechanically undistorted state of the substrate surfaces. During a bonding process between two unstructured substrates, displacement of individual parts also occurs in front, at and behind the bond wave. These displacements are caused by the mechanical forces that the advancing bond wave exerts on its surroundings. By way of example, it can be imagined that the second substrate is fixed in a fully planar manner by a lower substrate holder. Parts of the substrate are therefore not able to displace by displacement, bending or rotation. However, the first substrate dropped onto the second substrate can be compressed, stretched, rotated or bent as the bond wave advances. These elastic displacements are only minimal, but after the bond wave has passed through, they are fixed by the direct bonding that develops behind the bond wave. If we now imagine the initially defined grids on both substrate surfaces, we can see that at least one grid, in particular the grid of the first substrate, is no longer idealized, perfect and highly symmetrical. Its grid lines have been displaced. If the displacements change as a function of location, the corresponding distortions also arise.

An analogous consideration applies to structured substrates that have, for example, functional units or TSVs. Simplified it is added that one does not have to imagine a raster any more, but can orientate oneself immediately at the structures, which are to be brought in particular to the congruence.

Preferably, the method is applied to structured and/or unstructured first and second substrates. It is of particular advantage to use unstructured substrates to develop a first, approximate model. Unstructured first and second substrates are inexpensive, in contrast to already processed first and second substrates. By performing several test runs with unstructured first or second substrates, one is able to calculate composite models in which at least the influence of ambient temperature, ambient pressure, substrate thicknesses, substrate curvatures, and locally varying substrate curvatures can be estimated. In particular, these models can then be used as initial models for comparatively expensive patterned substrates. The patterned first and second substrates, respectively, can then be used to refine the composite model.

The at least one first geometrical parameter and/or at least one second geometrical parameter and/or the third geometrical parameter more preferably comprises the thickness as a function of a position, the local curvatures as a function of a position and/or the global curvature of the first substrate, the second substrate and/or the composite substrate. It is also conceivable that a geometrical parameter is understood to be a local displacement of the substrate surfaces that is externally accessible and measurable by a detector. Such a displacement can be related to displacements at the bond interface that are not accessible to a detector from the outside. It is also conceivable to measure the surface roughness of the substrate surfaces to be bonded as a function of a position. In particular, the surface roughness can influence the movement of the bond wave. Preferably, the thickness as a function of position, the local curvatures as a function of position, and the global curvature of the composite substrate are determined. More preferably, only the external, accessible properties of the composite substrate are measured, i.e., the local and global curvatures and the composite substrate thickness as a function of location. The survey of the composite substrate is also referred to as the survey of the outer shell of the composite substrate. In the further course of the text, this refers to the measurement of all externally accessible measured variables of the composite substrate, which preferably contribute to the geometric shape of the composite substrate. Thus, it is more preferably not necessary to investigate the bonded interface between the two substrates by means of a transmission method. This proves to be particularly advantageous for substrates that are at least partially non-transparent to electromagnetic radiation. For example, very many substrates are provided with metallic layers or metallic functional units, which make transmission investigation by means of infrared impossible, since metals absorb infrared radiation very well. In general, however, it can be assumed that an undesired displacement of the substrate surfaces relative to each other has taken place during an initial bonding process. Particularly in the case of substrates that have structures, the structures on both substrates will therefore not yet contact each other optimally, i.e. there will be displacement between the structures of the first substrate towards the structures of the second substrate. Thus, it is even possible to displace here, which could not be quantified in the prior art so far.

The geometrical parameters are preferably measured by imaging on the substrate and/or by interferometric methods and devices.

Preferably, a device is used which records a full-area interference pattern of a substrate surfaces from which the spatially resolved displacements and/or curvatures of the substrate or the substrate stack can be deduced.

The resolution of the camera that records the all-over real world image or interference image also determines the accuracy of the method. The higher the resolution of the camera, the more accurate the method according to the invention can be.

The geometrical parameters are preferably measured by evaluating the images from a digital camera, in particular with a CMOS or CCD sensor. In order to be able to measure the geometrical parameters, the highest possible resolution or pixel density is necessary. The more pixels there are per unit area, the more accurately a geometrical parameter can be determined. The number of pixels is best specified per unit line to have an idea of how many pixels are in a spatial dimension. It is advantageous to specify the number of pixels per wafer diameter. The number of pixels per wafer diameter is greater than 1000, preferably greater than 10000, more preferably greater than 25000, most preferably greater than 35000, most preferably greater than 50000. The resolution of the camera in megapixels (MP) is then greater than 1 MP, preferably greater than 100 MP, more preferably greater than 625 MP, most preferably greater than 1225 MP, most preferably greater than 2500 MP. The measurement of geometrical parameters on a substrate surfaces is preferably performed by taking an interference image. Due to an, in particular, full-area illumination of a, generally curved and/or distorted, substrate surfaces, phase differences occur due to different path lengths, which lead to an interference image. The curvatures and/or distortions can then be deduced from the interference image.

For bonding, the first substrate and the second substrate are preferably aligned with each other. The alignment is carried out using an aligner provided for this purpose. The alignment markers are preferably located on the periphery of the substrates. If unstructured substrates are bonded together, precision alignment can be dispensed with, especially if there are no alignment markers on the substrates. The substrates can then only be aligned to each other mechanically. However, it would be conceivable to apply simple alignment markers to the unstructured substrates in order to prevent the influence of an imprecise, purely mechanical alignment from becoming part of the model calculated later.

In the composite model, more preferably a two-dimensional displacement map is inserted between the substrate surfaces of the simulated substrates to be bonded together. This displacement map models the physical effect of the propagating bond wave. It mathematically describes how much the structures of the first substrate are displaced relative to the structures of the second substrate when initial and boundary conditions are specified. For unstructured substrates, the imaginary grid is used. The displacement map is ideally described by a vector analytic function, but in the simplest case it can be just a set of pairs of tuples. The first element of the pair tuple represents the position in the interface, the second element of the pair tuple is a displacement vector. Therefore, the displacement map can also be given in tabular form. In the first, especially the left, column the position in the interface is given, in the second column the displacement vector is given. With the help of the displacement map, it is thus possible to represent with on-site resolution how far a structure on the substrate surface of a first substrate is displaced from the structure on the substrate surface of a second substrate.

An absolute value of a displacement vector is between 0 nm and 100 μm, preferably between 0 nm and 10 μm, more preferably between 0 nm and 1 μm, most preferably between 0 nm and 100 nm, most preferably between 0 nm and 10 nm.

Preferably, the composite model is generated in an analysis and/or simulation device, for example in a computer, with the aid of which a substrate stack can be simulated after bonding. Preferably, the term analysis and/or simulation device may refer to a (personal) computer, a virtual machine running on host hardware, a microcontroller or an integrated circuit. Alternatively, the analysis and/or simulation device may be a real or a virtual group of computers (the technical term for a real group of computers is “cluster”, the technical term for a virtual group of computers is “cloud”). Preferably, the analyzer comprises a computing unit and a memory unit. A computing unit may comprise hardware and software elements, for example, a microprocessor or a field programmable gate array. A memory unit or a storage device can be implemented as a non-permanent working memory (e.g. random access memory) or as a permanent mass storage device (e.g. hard disk, USB stick, SD card, solid state disk). Furthermore, it is also conceivable that the analysis device comprises at least one server and uses at least one platform or network of multiple servers that support each other in performing the method.

A substrate stack comprises at least two substrates. It is also conceivable to use substrate stacks with more than two substrates (multistacks).

It is more preferably intended to use measured geometrical parameters of the first and the second substrate before bonding to generate simulated composite substrates in the analysis and/or simulation device. In addition, a displacement map is generated with the analysis and/or simulation device, which in turn can be used to calculate a simulated third geometrical parameter. At the end of the calculation of the simulated third geometrical parameter, the simulated third geometrical parameter can be compared to the measured third geometrical parameter. For example, the third geometrical parameter is the overall external shape or geometry of the composite substrate. If both geometries or geometrical parameters are the same, it can be assumed that the preliminary displacement map corresponds to the real displacement map. This method step will now be described in more detail.

More preferably, the composite model is determined and provided in a preparatory method step. One challenge is to determine the composite model on the one hand and to find the correct displacement map on the other hand. This is facilitated by bonding and measuring several composite substrates. The composite model is approximated in a preparatory method step by means of a large number of bonding processes and the measured variables, in particular geometrical parameters, measured during the bonding processes. Once the composite model has been established in the preparatory method step, more preferably a variation of the preliminary displacement map is realized in the analysis and simulation device until the simulated third geometrical parameter is identical to a measured third geometrical parameter. In the following, the determination of the composite model in the preparatory method step will be discussed.

It can be assumed that in an actual bond, the environmental parameters such as temperature, ambient pressure, atmosphere, etc. are the cause of the real displacement maps. In the model, it is therefore sufficient to vary only the displacement map until the outer shell of the bonded, simulated substrate stack is identical to the outer shell of the measured substrate stack. Once this displacement map is found, all environmental parameters can be automatically associated with it. The model therefore preferably correlates only the displacement map with the outer envelope of the simulated composite substrate or, more simply, with the simulated composite substrate.

In a first method, the computation of the model by the simulated displacement maps is preferably performed using the finite element method (FEM) or using the finite difference method (FDM). With known initial and boundary conditions of the individual substrates and a given displacement map, the problem is simply one of the theories of elasticity. The finite element method is simply used to compute how the substrate stack deforms given a displacement map. However, FEM and FDM methods are relatively time consuming.

In a second method, the computation of the model is done using a set of mathematical basis functions. The, preferably linear, superposition of the basic functions allows the computation of a simulated bonded substrate stack for a given displacement map. The basic functions have model parameters that can be found using appropriate methods, thus building the basic functions themselves.

In a third method, the computation of the model is performed by artificial intelligence, in particular neural networks.

The basic functions or the FEM models have self-adaptable model parameters that are determined by the collected data sets, preferably by a minimization task. Once these model parameters have been determined, a model is available that can be used to compute the displacement maps from the fit parameters or the fit parameters from the displacement maps.

During the optimization it is possible to use the single local displacements as fit parameter as well as models for the local displacements (4 parameter model, 6 parameter model, HOWA, Zernike polynomials, Legendre polynomials etc.) to re-duce the number of variables. When using models, more or less residual error will remain depending on the complexity of the model.

The following simplifications can be made when creating models.

Preferably, the computation of the model parameters exploits the symmetry of the system. It is conceivable, for example, to have the system as axially symmetrical with respect to its mechanical properties, neglecting the orthotropy that is usually present, and thus to simplify the computation decisively. The basic functions or FEM models are then used only for the computation of a small part of a surface. The computation of the remaining parts is done by exploiting and applying symmetry.

It is also conceivable to neglect the initial shapes and thicknesses of the individual substrates and simply use the standard thicknesses according to the so-called semi-specification.

The following additional information leads to a more detailed and complex composite model:
Use of all available information from the initial substrates, i.e., the shape of the backsides/faces combined with the measured local thickness, and/or
Using known information about the layers on the substrate (e.g. metal layers, oxide layers under stress, etc.).

Preferably, the comparison is intended to be iteratively repeated for different preliminary displacement maps until the displacement map is determined. This allows the displacement map to be determined by a comparatively simple algorithm.

More preferably, the displacement map is determined for a first set of parameters describing a first bonding process, and a further displacement map is determined for a second set of parameters describing a second bonding process, further comprising;
comparing the displacement map and the further displacement map, and
establishing a third set of parameters to be used for a third bonding process, the set of parameters depending on the comparison between the displacement map and the further displacement map. Thus, it is advantageously possible to use the displacement maps to compare different bonding processes and their chances of success.

The first set of parameters and/or the second set of parameters and/or the third set of parameters comprises at least one parameter, more preferably the global, statistically averaged ambient temperature. Preferably, a temperature map of at least one substrate, preferably both substrates, is also recorded as a function of time and understood as a parameter to provide an indication of how the temperature in the vicinity of the bond wave front behaves thermally as the bond wave advances, as well as the upstream and downstream surface regions.

In a further improvement, the global statistically averaged ambient pressure is measured and assigned to the set of parameters.

In a further improvement, an apparatus for bonding has a plurality of flow sensors arranged radially symmetrically, preferably at equal angular intervals. The flow sensors lie within the plane through which the bonding interface passes. They point to the contacting point where the bonding started, in particular the centre of the two substrates. The purpose of the flow sensors is to measure the airflow that is created as the bond wave advances. The bond wave presses the air located between the first substrate and the second substrate radially symmetrically outward. The air cushion thus created between the first substrate and the second substrate influences how quickly the first substrate bonds to the second substrate. Therefore, for example, an influence on the bonding behaviour can also be achieved by changing the gas composition. By adding very light elements such as helium, the gas kinetics and thus the associated mechanical behaviour of the first and second substrates, especially the falling first substrate, can be influenced. Therefore, the measurement results of these flow sensors are also more preferably part of the set of parameters.

In a further improvement, the atmospheric composition is determined and used as part of the set of parameters. Of particular importance is the determination of the humidity of the air, i.e., the water content in the atmosphere. Experience has shown that humidity has a massive influence on a bonding result. The water can condense on the substrate surfaces and thus contribute to an improvement of the bonding quality, especially if the substrate surfaces are hydrophilic.

In a further improvement, the settings by which the deformation means, by means of which at least one substrate is deformed, are recorded during the deformation. If the deformation means is a pin, the position of the pin, its velocity and the force acting on the substrate are preferably measured as a function of time. The position is preferably determined directly by the step of a stepper motor, preferably by other measuring means. Velocity and acceleration are automatically obtained as first and second derivatives from the distance-time diagram. The force is preferably measured by a load cell. The load cell is either built into the pin or located on the side or behind the pin. In these two cases, easy replacement is guaranteed. If the deformation means is a nozzle, the flow speed, the pressure and the volumetric flow of the escaping gas are preferably measured.

Preferably, it is provided that a temporal development of the at least one parameter during the bonding process is determined by means of the at least one measuring device. In this way, it can be taken into account with advantage that at least certain parameters can change during bonding processes.

In particular, it is provided that a thickness of the first substrate and/or a thickness of the second substrate has a value between 100 nm and 5000 um, preferably between 100 nm and 800 μm, and most preferably between 100 nm and 500 μm. Thus, the substrates to be bonded are comparatively thin substrate layers. The substrates can be of any shape, but are more preferably circular. The diameter of the substrates is standardized, especially in industry. For wafers, the standard industrial diameters are 1 inch, 2 inches, 3 inches, 4 inches, 5 inches, 6 inches, 8 inches, 12 inches and 18 inches.

Preferably, subsegments of the displacement map are simulated. For example, subsegments are understood as sections in a grid of the displacement map or subsections of the displacement map. In this way, for example, the significance or relevance of individual subsegments can be increased.

Preferably, it is intended that mechanical learning is used to determine the composite model and/or the at least one parameter for the third set of parameters. In particular, it is conceivable that the determined displacement maps are stored together with the parameters of the bonding process and are used as training data to optimize the composite model or the parameter setting in the bonding process. Preferably, the training data is shared globally, for example via a cloud, to assist the analysis and/or simulation devices in finding the optimal composite model or bonding parameters.

Another subject matter of the present invention is a method of setting parameters for a bonding process, wherein displacement maps are provided for setting parameters to determine parameters for the bonding process based on the displacement map, wherein the displacement maps are provided by means of a method according to the present invention. All advantages and specifications described for the method of providing the displacement map apply analogously to the method of setting parameters and vice versa.

Another subject matter of the present invention is a composite substrate made of a first substrate and a second substrate in a bonding process using the parameters set according to a method according to the invention. All advantages and properties described for the method of setting parameters apply analogously to the composite substrate and vice versa.

Another subject matter of the present invention is an apparatus for measuring and/or bonding a first substrate, a second substrate to a composite substrate, respectively, and a composite substrate:
comprising at least one analysis and/or simulation device suitable and adapted to perform the disclosed method. All advantages and properties described for the method for providing the displacement map apply analogously to the apparatus and vice versa. More preferably, the apparatus is intended to comprise means for bonding. For example, a bonder is configured to carry out the method of bonding according to the invention.

Most preferably, it is intended that the apparatus comprises at least one measuring device. Preferably, the measuring device is adapted to determine a parameter in the bonding process and/or a first, second and/or third geometrical parameter.

The method according to the invention can be applied directly after bonding. However, it is also conceivable that the method is applied only after mechanical and/or chemical processing, in particular re-thinning, of the bonded substrate stack. The processing of the substrate stack changes the geometrical parameters, such as the thickness and/or the curvature. It can be assumed that the displacement map in the bonding interface is not affected by such subsequent processing of the substrate stack.

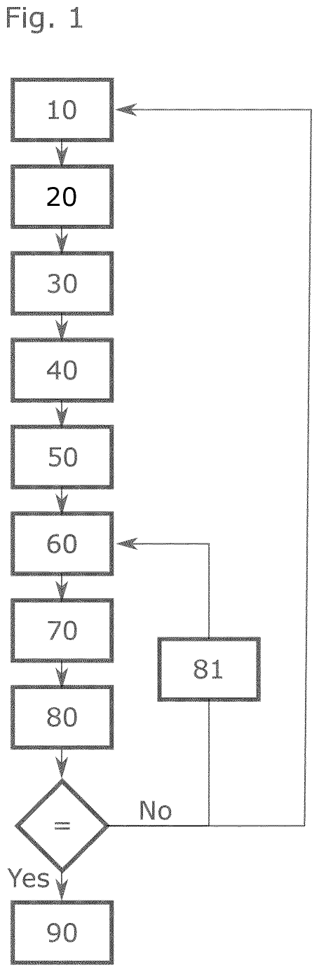

FIG. 1 shows a process flow of a method according to a first preferred embodiment of the present invention. In a first method step 10, a first substrate 1 and a second substrate 2 are selected. In a second method step 20, the first substrate 1 and the second substrate are measured, in particular to determine at least one first geometrical parameter for the first substrate 1 and to determine at least one second geometrical parameter for the second substrate 2. In an optional, third method step 30, the first substrate 1 and the second substrate 2 are aligned with respect to each other, preferably in an alignment device that holds and positions, for example, the first substrate 1 with a first holding fixture and the second substrate 2 with a second holding fixture. In a fourth method step 40, the first substrate 1 and the second substrate 2 are bonded, i.e. joined, to each other. In a fifth method step 50, the bonded composite substrate, i.e., the composite substrate, is measured to determine a measured third geometrical parameter. In a sixth method step 60, a composite model including a displacement map or based on a use of a displacement map is generated in an analysis and/or simulation device. The analysis and/or simulation device comprises at least one microprocessor and is, for example, a computer. It is also conceivable that the analysis and/or simulation device is part of a network and/or cloud-based.

In a seventh method step 70, a simulated third geometrical parameter for a simulated composite substrate is determined or calculated using the first geometrical parameter and the second geometrical parameter determined in the second method step 20 and the simulated displacement map from the sixth method step 60. In an eighth method step 80, the at least one measured third geometrical parameter is compared to the simulated at least one third geometrical parameter to determine the extent to which the simulated composite substrate matches or deviates from the real, i.e. bonded and measured, composite substrate. If the simulated composite substrate matches the real composite substrate, in particular with respect to the simulated third geometrical parameter and the measured third geometrical parameter, the displacement map simulated in the analysis and/or simulation device is identical to the real displacement map and the method is terminated with the ninth method step 90. The simulated displacement map is then the final displacement map provided by the method.

If the simulated composite substrate and the simulated composite substrate are not identical, the last displacement map from the sixth method step 60 is changed in a supplementary method step 81, in particular varied by a mathematical method, and thus results in a new displacement map, with the aid of which the simulation starts again. Optionally, it is possible to start the method from the beginning for a specified model with new substrates. In this case, the method starts again at the first method step 10.

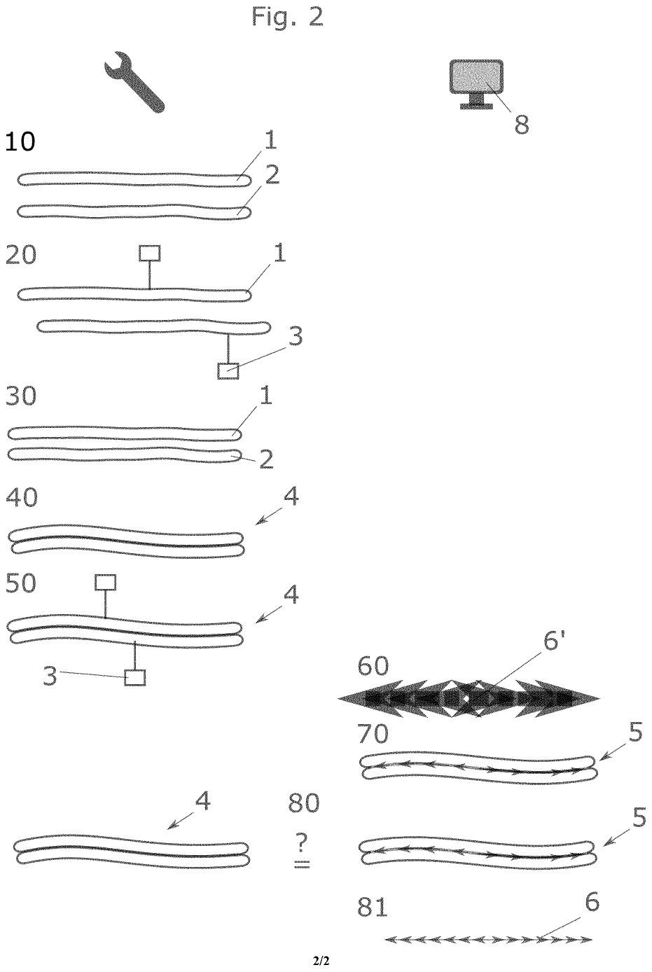

FIG. 2 shows the measuring and simulation steps of FIG. 1 again schematically. Components occurring twice in a method step are always marked only once with a reference sign. The method steps not performed in the analysis and/or simulation device are shown in the left column, those performed in the analysis and/or simulation device in the right column.

### REFERENCE NUMBERS

1 first substrate
2 second substrate
4 composite substrate
5 simulated composite substrate
6 preliminary displacement map
6′ displacement map
8 analysis and/or simulation device
10 first method step
20 second method step
30 third method step
40 fourth method step
50 fifth method step
60 Sixth method step
70 Seventh method step
80 eighth method step
81 Supplementary method step
90 Ninth method step

1. A method for providing a displacement map (6), comprising,
providing a first substrate (1) and a second substrate (2),
measuring the first substrate (1) to determine at least a first geometrical parameter and/or a microscopic first geometrical parameter, and the second substrate (2) to determine at least a second geometrical parameter,
bonding the first substrate (1) to the second substrate (2) to form a composite substrate (4),
measuring the bonded composite substrate (4) to determine at least one measured third geometrical parameter,
providing at least one simulated third geometrical parameter for the bonded composite substrate (4) based on a composite model, wherein the simulated third geometrical parameter is provided as a function of the at least one first geometrical parameter, the at least one second geometrical parameter, and a preliminary displacement map (6′), indicating a local deviation from the desired ideal position, is simulated on the basis of the composite model by means of an analysis and/or simulation device (8), wherein the preliminary displacement map (6′) is created by means of the analysis and/or simulation device (8),
comparing the at least one simulated third geometrical parameter with the at least one measured third geometrical parameter, and
providing as a displacement map (6) that preliminary displacement map (6′) for which the deviation between the simulated third geometrical parameter and the at least one measured third geometrical parameter is minimal.

2. The method according to claim 1, wherein the preliminary displacement map (6′) is adjusted at least once to find the preliminary displacement map (6′) with the minimum deviation between the simulated third geometrical parameter and the at least one measured third geometrical parameter.

3. The method according to claim 1, wherein in a preparatory method step the composite model is determined and provided.

4. The method according to claim 1,, wherein the at least one first geometrical parameter and/or the at least one second geometrical parameter and/or the third geometrical parameter comprises a thickness as a function of a position, a locally measured curvature as a function of a position and/or the global curvature of the first substrate (1) and/or the second substrate (2).

5. The method according to claim 1, wherein for a first set of parameters describing a first bonding process the displacement map (6) and for a second set of parameters describing a second bonding process a further displacement map is determined, further comprising:
comparing the displacement map and the further displacement map, and
establishing a set of parameters to be used for a third bonding process, the set of parameters depending on the comparison between the displacement map (6) and the further displacement map.

6. The method according to claim 1, wherein at least one parameter of the first set of parameters and/or the second set of parameters is determined during the bonding process by means of at least one measuring device.

7. The method of claim 6, wherein a temporal development of the at least one parameter during the bonding process is determined by means of the at least one measuring device.

8. The method according to claim 4, wherein the at least one parameter of the first set of parameters comprises a temperature, a pressure and/or a flow quantity during the bonding.

9. The method according to claim 1, wherein the first substrate (1) and the second substrate (2) are unstructured.

10. The method according to claim 1, wherein a thickness of the first substrate (1) and/or a thickness of the second substrate (1) has a value between 100 nm and 5000 μm.

11. A method of setting parameters for a bonding process, wherein displacement maps (6) are created for setting the parameters to determine parameters for the bonding process based on the displacement maps (6), wherein the displacement maps (6) are provided by means of the method according to claim 1.

12. A composite substrate (4) made of a first substrate and a second substrate in a bonding process using the parameters determined according to the method according to claim 11.

13. An apparatus for measuring a first substrate (1), a second substrate (2) and/or a composite substrate (4) comprising at least one analysis and/or simulation device (8) suitable and adapted to perform the method according to claim 1.

14. The apparatus according to claim 13, wherein the apparatus comprises means for bonding the first substrate (1) and the second substrate (2) into a composite substrate (4).

15. The apparatus according to claim 13, wherein the apparatus comprises means for capturing an all-over interference image.
